(19) United States
(12) Patent Application Publication
(10) Pub. No.: US 2025/0096697 A1
(43) Pub. Date: Mar. 20, 2025

(54) POWER CONVERSION APPARATUS

(71) Applicant: FUJI ELECTRIC CO., LTD., Kawasaki-shi (JP)

(72) Inventor: Takanori SHINTANI, Suzuka-shi (JP)

(21) Appl. No.: 18/788,151

(22) Filed: Jul. 30, 2024

(30) Foreign Application Priority Data
Sep. 20, 2023 (JP) 2023-152240

(51) Int. Cl. H02M 7/00; H05K 7/20

(52) U.S. Cl. CPC H02M 7/003; H05K 7/20927

(57) ABSTRACT

A power conversion apparatus includes a boost converter including a reactor formed of a resin to include a coil a part of which is exposed by resin molding. The reactor is arranged to bring the exposed coil part, which is exposed from the resin, of the coil in contact with a contact part of a lid to be in contact with the reactor.

### CROSS-REFERENCE TO RELATED APPLICATION

This application claims priority of Japanese Patent application number JP2023-152240, power conversion apparatus, Sep. 20, 2023, Takanori Shintani, disclosure of which is herein incorporated.

### BACKGROUND

### Field of the Invention

The present application relates to a power conversion apparatus.

### Description of the Background Art

Power conversion apparatuses including a base in which a cooling flow path is formed are known in the art. Such a power conversion apparatus is disclosed in Japanese Patent Laid-Open Publication No. JP2023-53944, for example.

Japanese Patent Laid-Open Publication No. JP2023-53944 discloses a power conversion apparatus including a base including a cooler main part in which a cooling flow path is formed, and a lid that is arranged to cover the cooling flow path of the cooler main part. The power conversion apparatus disclosed in Japanese Patent Laid-Open Publication No. JP2023-53944 includes a reactor accommodated in a box-like-shaped lid that is formed of a metal and dedicated for the reactor. The box-like-shaped lid dedicated for the reactor is arranged to cover a hole formed in the lid, which is arranged to cover the cooling flow path. Heat generated by the reactor is dissipated to the cooling flow path through the box-like-shaped lid dedicated for the reactor.

However, in the known power conversion apparatuses as disclosed in Japanese Patent Laid-Open Publication No. JP2023-53944, because the box-like-shaped lid dedicated for the reactor is arranged to cover the hole formed in the lid, which is arranged to cover the cooling flow path, it is necessary to provide a sealing structure for sealing between the box-like-shaped lid dedicated for the reactor and the lid, which is arranged to cover the cooling flow path. In this case, a structure for cooling the reactor becomes relatively complicated. For this reason, a power conversion apparatus that can simplify the structure for cooling the reactor is desired.

### SUMMARY

The present invention is intended to solve the above problem, and one object of the present invention is to provide a power conversion apparatus capable of simplifying a structure for cooling a reactor.

In order to attain the aforementioned object, a power conversion apparatus according to one aspect of the present application includes a boost converter for boosting direct current power input from a direct current power supply; an inverter for converting the direct current power boosted by the boost converter into alternate current power and supplying the alternate current power to a load; a direct current/direct current converter for transforming the direct current power input from the direct current power supply; and a base on which the boost converter, the inverter, and the direct current/direct current converter are arranged, wherein the base includes a cooler main part including a cooling flow path formed in the cooler main part, and formed of a metal, and a lid arranged to cover the cooling flow path of the cooler main part, and formed of a metal, the boost converter includes a reactor formed to include a coil a part of which is exposed by resin molding, and the reactor is arranged to bring the exposed coil part, which is exposed from the resin, of the coil in contact with a contact part of the lid to be in contact with the reactor.

In the power conversion apparatus according to the aforementioned one aspect of the present application, as discussed above, the boost converter includes a reactor formed of a resin to include a coil a part of which is exposed by resin molding, and the reactor is arranged to bring the exposed coil part, which is exposed from the resin, of the coil in contact with a contact part of the lid to be in contact with the reactor. According to this configuration, because the exposed coil part is in contact with the lid through the contact part, heat generated from the reactor can be dissipated to the cooling flow path covered by the lid without providing a box-like-shaped lid or the like for dedicated the reactor. In this case, because such a box-like-shaped lid or the like for dedicated the reactor is not necessarily provided, it is not necessary to provide a sealing structure for sealing between the box-like-shaped lid dedicated for the reactor and the lid arranged to cover the cooling flow path. Consequently, it is possible to simplify a structure for cooling the reactor. In addition, because the box-like-shaped lid dedicated for the reactor is not provided, it is possible to correspondingly reduce a weight of the power conversion apparatus, and to reduce the number of parts of the power conversion apparatus.

In the power conversion apparatus according to the aforementioned aspect, it is preferable that the exposed coil part has a rectangular shape as viewed in a direction in which the reactor and the lid are aligned; and that the contact part has a rectangular shape that overlaps the exposed coil part as viewed in the direction in which the reactor and the lid are aligned. According to this configuration, because the contact area having the rectangular shape overlaps the exposed coil part having the rectangular shape, it is possible to easily increase a contact area between the exposed coil part and the exposed coil part.

In the power conversion apparatus according to the aforementioned aspect, it is preferable that the contact part is formed to protrude from the lid toward an exposed coil part side. According to this configuration, because the contact part protrudes from the lid toward the exposed coil part side so that a distance between the exposed coil part and the contact part becomes closer than a distance between the exposed coil part and other part of the lid other than contact part, it is possible to easily bring the exposed coil part in contact with the contact part.

In the configuration in which the contact part is formed to protrude from the lid toward the exposed coil part side, it is preferable that the contact part has a protrusion height that forms a gap between a part of a surface of the reactor on the exposed coil part side other than the exposed coil part and the lid with the contact part being in contact with the exposed coil part. According to this configuration, because a gap is formed between the part of the surface of the reactor on the exposed coil part side other than the exposed coil part and the lid with the contact part being in contact with the exposed coil part, it is possible to prevent that contact between the part of the surface of the reactor on the exposed coil part side other than the exposed coil part and the lid obstructs contact of the contact part with the exposed coil part.

In the power conversion apparatus according to the aforementioned aspect, it is preferable that the exposed coil part has a convex shape that protrudes toward a lid side; and that the contact part is arranged at a position corresponding to the convex shape of the exposed coil part, and has a concave shape that is recessed toward the lid side. According to this configuration, because the exposed coil part, which has a convex shape that protrudes toward the lid side, can be brought in contact with the contact part, which is arranged at the position corresponding to the convex shape of the exposed coil part, and has a concave shape that is recessed toward the lid side, it is possible to easily increase a contact area between the exposed coil part and the exposed coil part.

In the configuration in which the exposed coil part has a rectangular shape as viewed in a direction in which the reactor and the lid are aligned, and the contact part has a rectangular shape that overlaps the exposed coil part as viewed in the direction in which the reactor and the lid are aligned, it is preferable that two exposed coil parts each of which has an elongated rectangular shape as viewed in the direction in which the reactor and the lid are aligned are arranged as the exposed coil part in an extension direction of a shorter side of the elongated rectangular shape; and that two contact parts each of which has an elongated rectangular shape that overlaps corresponding one of the two exposed coil parts as viewed in the direction in which the reactor and the lid are aligned are aligned with each other in the extension direction of the shorter side of the elongated rectangular shape as the contact part. According to this configuration, because each of the two contact areas having the elongated rectangular shape overlaps corresponding one of the two exposed coil parts having the elongated rectangular shape, it is possible to easily increase contacts area between the exposed coil parts and the exposed coil parts.

In the power conversion apparatus according to the aforementioned aspect, it is preferable that a cooling fin protruding into the cooling flow path is formed at a position of a surface of the lid on a cooling flow path side corresponding to the contact part. According to this configuration, it is possible to efficiently cool the lid by the cooling liquid flowing in the cooling flow path through the cooling fin. Consequently, it is possible to efficiently dissipate heat generated from the reactor to the cooling flow path covered by the lid.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram of a power conversion apparatus according to one embodiment of the present invention.

FIG. 2 is a perspective view showing the power conversion apparatus according to the one embodiment of the present invention.

FIG. 3 is a side view of the power conversion apparatus according to the one embodiment of the present invention.

FIG. 4 is a perspective view showing a boot inverter lid and a direct-current/direct-current-converter lid according to the one embodiment of the present invention.

FIG. 5 is a perspective view showing the boot inverter lid and the direct-current/direct-current-converter lid according to the one embodiment of the present invention in an overlapping state.

FIG. 6 is a perspective view showing the boot inverter lid and the direct-current/direct-current-converter lid according to the one embodiment of the present invention as viewed from a back surface side.

FIG. 7 is a perspective view showing the boot inverter lid and the direct-current/direct-current-converter lid according to the one embodiment of the present invention in the overlapping state as viewed from the back surface side.

FIG. 8 is a cross-sectional view of a seal groove and a seal according to the one embodiment of the present invention taken along a YZ plane.

FIG. 9 is a cross-sectional view of contact parts between a reactor and the boost-converter lid according to the one embodiment of the present invention taken along the YZ plane.

FIG. 10 is a perspective view showing the reactor according to the one embodiment of the present invention as viewed from the back surface side.

FIG. 11 is a cross-sectional view of a converter switching element according to the one embodiment of the present invention taken along the YZ plane.

### DESCRIPTION OF THE PREFERRED EMBODIMENT

Embodiments embodying the present invention will be described with reference to the drawings.

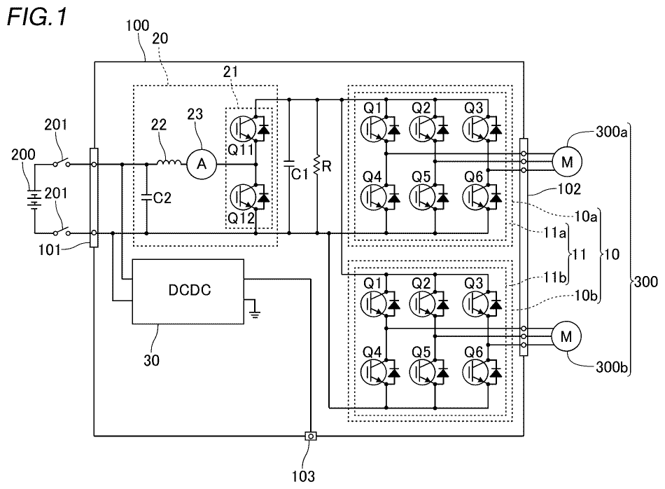

A configuration of a power conversion apparatus 100 according to one embodiment of the present application will be described with reference to FIGS. 1 to 11. The power conversion apparatus 100, for example, is installed on a vehicle.

### (Circuit Configuration of Power Conversion Apparatus)

As shown in FIG. 1, the power conversion apparatus 100 converts direct current power input from a direct current power supply 200 through a connector 101, and supplies the power converted to a load 300 through a connector 102. Switches 201 are connected between the power conversion apparatus 100 and the direct current power supply 200.

The power conversion apparatus 100 includes an inverter 10, a boost converter 20, a capacitor C1, a resistor R, and a direct current/direct current converter 30.

The inverter 10 converts direct current power input from the direct current power supply 200 into alternate current power, and supplies the alternate current power to the load 300.

The inverter 10 includes switching element modules 11. The switching element modules 11 convert direct current power into alternating current power. Each switching element module 11 includes semiconductor switching elements Q1, Q2 and Q3 that construct an upper arm, and semiconductor switching elements Q4, 05 and Q6 that construct a lower arm.

The inverter 10 includes a first inverter 10a and a second inverter 10b. Switching element modules 11 include a first switching element module 11a included in the first inverter 10a, and a second switching element module 11b included in the second inverter 10b. Also, the loads 300 include a first load 300a and a second load 300b. The first inverter 10a converts the direct current power input from the direct current power supply 200 into alternate current power, and supplies the alternate current power to the first load 300a through the connector 102. The second inverter 10b converts the direct current power input from the direct current power supply 200 into alternate current power, and supplies the alternate current power to the second load 300b through the connector 102.

The boost converter 20 is arranged on an input side of the inverter 10. The boost converter 20 increases a voltage of the direct current power input from the direct current power supply 200 through the connector 101. The boost converter 20 supplies the voltage increased to the inverter 10. In other words, the inverter 10 converts the direct current power boosted by the boost converter 20 into alternate current power, and supplies the alternate current converted to the load 300.

The boost converter 20 includes a boost switching element module 21, and a reactor 22. The boost switching element module 21 includes boost switching elements Q11 and Q12. The boost switching elements Q11 and Q12 construct the upper and lower arms, respectively. In addition, the boost converter 20 includes a capacitor C2. The reactor 22 is connected between a positive side of the direct current power supply 200, and a connection point between the boost switching element Q11 and the boost switching element Q12. The capacitor C2 is connected in parallel to the boost switching element Q12.

The boost converter 20 includes a current sensor 23. The current sensor 23 measures a current that flows through the boost converter 20. The current sensor 23 is connected between the boost switching element module 21 and the reactor 22.

The capacitor C1 and the resistor R are connected between the boost converter 20 and the inverter 10. The capacitor C1 and the resistor R are connected in parallel to each other.

The direct current/direct current converter 30 transforms a direct current voltage input from the direct current power supply 200. The direct current/direct current converter 30 supplies the voltage transformed to an output terminal 103.

### (Structure of Power Conversion Apparatus)

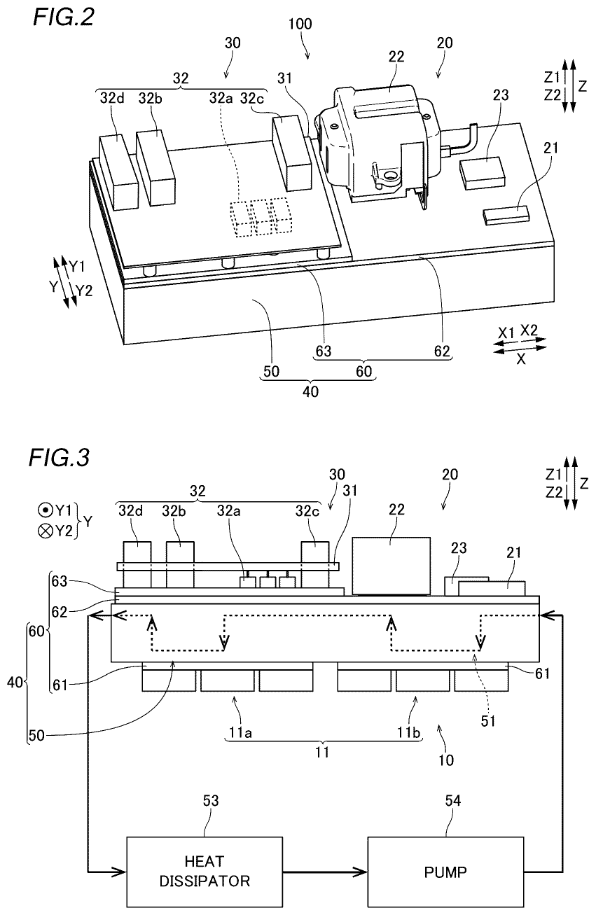

As shown in FIG. 2, the power conversion apparatus 100 includes a base 40 on which the boost converter 20, the inverter 10, and the direct current/direct current converter 30 are arranged. The boost converter 20 and the direct current/direct current converter 30 are arranged on a front surface side (Z1 side) of the base 40. The inverter 10 is arranged on a back surface side (Z2 side) of the base 40.

The base 40 includes a cooler main part 50 including a cooling flow path 51 formed in the cooler main part and formed of a metal, and a lid 60 arranged to cover the cooling flow path 51 of the cooler main part 50, and formed of a metal. The cooling flow path 51 is space inside the base 40 formed by the cooler main part 50 and the lid 60, which is arranged to cover an opening (not shown) formed in the cooler main part 50. A cooling liquid such as water or antifreeze flows through the cooling flow path 51. The cooler main part 50 and the lid 60 are formed of a metal having a relatively high thermal conductivity, such as aluminum. The boost converter 20, the inverter 10, and the direct current/direct current converter 30, which are arranged on the base 40, are cooled by the cooling liquid flowing through the cooling flow path 51.

The cooling liquid that flows out of the cooling flow path 51 is cooled by dissipating its heat by using a heat dissipator 53. The cooling liquid that is cooled by the heat dissipator 53 is fed by a pump 54, and flows back into the cooling flow path 51. The heat dissipator 53 includes a heat exchanger to be cooled by outside air. The heat dissipator 53 is a radiator, for example. Alternatively, the pump 54 can be connected between the outlet of the cooling flow path 51 and the heat dissipator 53 so that the cooling liquid before the heat dissipation by the heat dissipator 53 is fed by the pump 54.

### <Configuration of Lid>

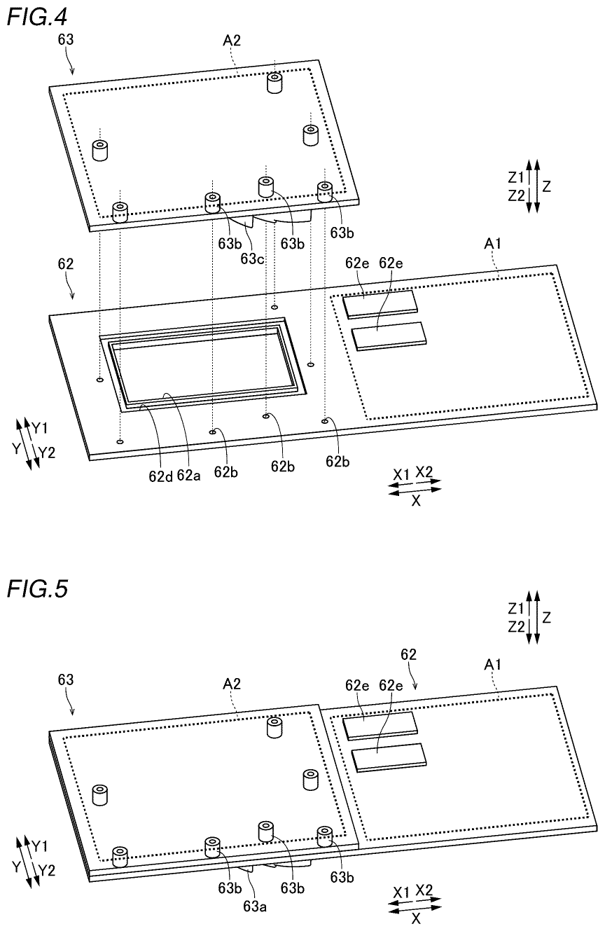

As shown in FIG. 3, the lid 60 includes an inverter lid 61, a boost-converter lid 62, and a direct-current/direct-current-converter lid 63. The inverter lid 61 is arranged on the back surface side (Z2 side) of the cooler main part 50 so as to include a placement area of the inverter 10. The boost-converter lid 62 is arranged on the front surface side (Z1 side) of the cooler main part 50, including the placement area A1 (see FIG. 4) for the boost converter 20. The direct-current/direct-current-converter lid 63 is arranged on the front surface side (Z1 side) of the cooler main part 50 so as to include a placement area A2 (see FIG. 4) for the direct current/direct current converter 30. The inverter 10 arranged on the inverter lid 61, the boost converter 20 arranged on the boost-converter lid 62, and the direct current/direct current converter 30 arranged on the direct-current/direct-current-converter lid 63 are cooled by the cooling liquid flowing through the cooling flow path 51.

The direct-current/direct-current-converter lid 63 is arranged on the direct current/direct current converter 30 side (Z1 side) with respect to the boost-converter lid 62 so as to exclude the placement area A1 (see FIG. 4) for the boost converter 20 and to overlap the boost-converter lid 62. Specifically, as shown in FIG. 4, the boost-converter lid 62 is arranged on the entire front surface side (Z1 side) of the cooler main part 50 so as to include the placement area A1 for the boost converter 20 and to overlap at least part of the placement area A2 for the direct current/direct current converter 30 as viewed in the Z direction. The direct-current/direct-current-converter lid 63 is arranged only in an X1-side part on the front surface side (Z1 side) of the cooler main part 50 so as to include the placement area A2 for the direct current/direct current converter 30 and to exclude the placement area A1 for the boost converter 20. Also, the direct-current/direct-current-converter lid 63, and an X1-side part of the boost-converter lid 62 are arranged in this order in the Z direction from the Z1 side to the Z2 side.

The boost-converter lid 62 has a through opening 62a formed at a position corresponding to the direct-current/direct-current-converter lid 63. The direct-current/direct-current-converter lid 63 is arranged in a part on the direct current/direct current converter 30 side (Z1 side) with respect to the boost-converter lid 62 so that the through opening 62a is closed by the direct-current/direct-current-converter lid 63. As shown in FIG. 5, the direct-current/direct-current-converter lid 63 and the boost-converter lid 62 are fixed by fastening fastening parts 63b of the direct-current/direct-current-converter lid 63 and the fastening parts 62b of the direct-current/direct-current-converter lid 62 to each other by using fasteners (not shown) with the through opening 62a of the boost-converter lid 62 being closed by the direct-current/direct-current-converter lid 63.

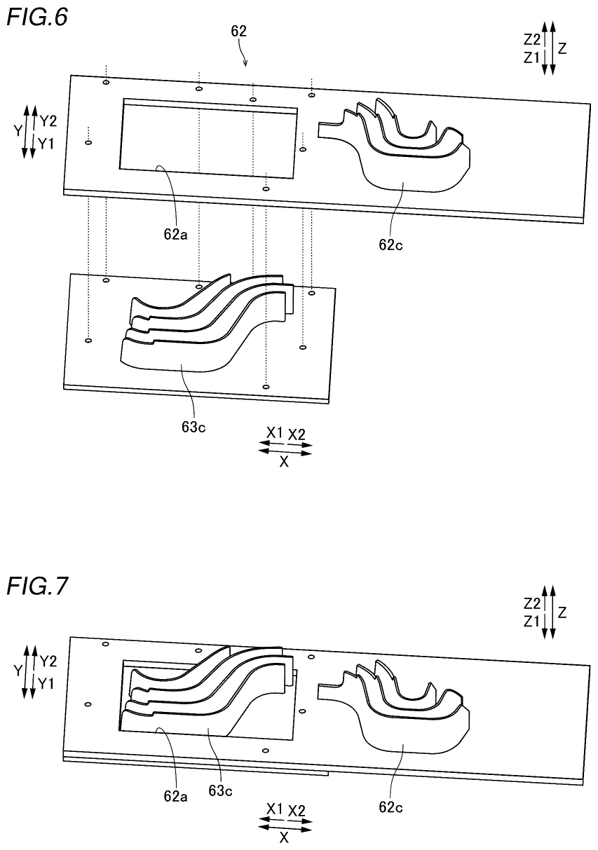

As shown in FIG. 6, cooling fins 62c protruding into the cooling flow path 51 are formed at positions of a surface of the boost-converter lid 62 on the cooling flow path 51 side (Z2 side) corresponding to contact parts 62e (described later). In addition, as shown in FIGS. 6 and 7, cooling fins 63c are formed on a surface of the direct-current/direct-current-converter lid 63 on the cooling flow path 51 side (Z2 side) to pass the through opening 62a of the boost-converter lid 62 so as to protrude into the cooling flow path 51. The cooling fins 62c and the cooling fins 63c have curved shapes extending in a flow direction of the cooling liquid in the cooling flow path 51.

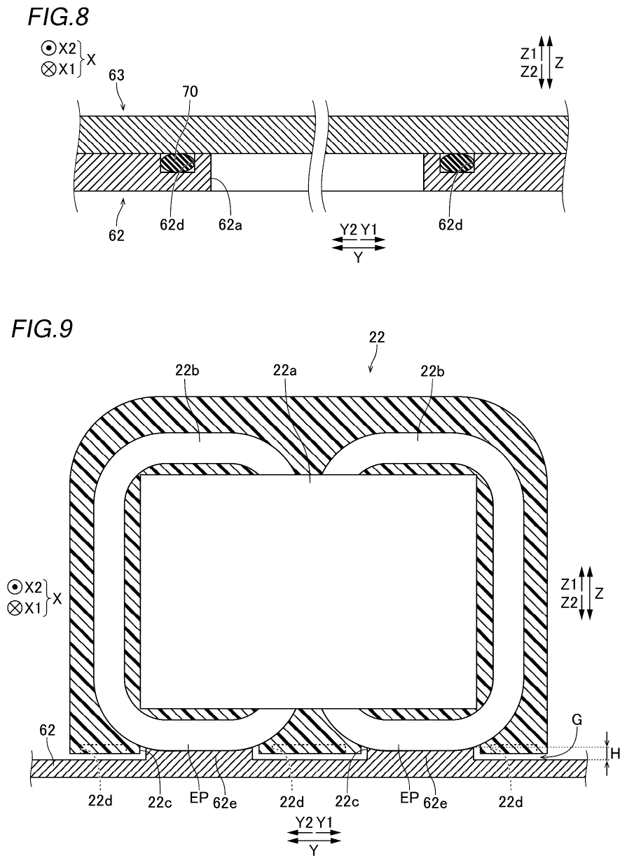

As shown in FIG. 4, a seal groove 62d is formed around the through opening 62a on the surface of the direct-current/direct-current-converter lid 63 side (Z1 side) of the boost-converter lid 62. In addition, as shown in FIG. 8, the power conversion apparatus 100 includes a seal 70 arranged in the seal groove 62d to seal between the boost-converter lid 62 and the direct-current/direct-current-converter lid 63. The seal 70 is a rubber O-ring, for example.

### <Configuration of Reactor>

As shown in FIG. 2, the reactor 22 is arranged in a part of the placement area A1 (see FIG. 4) for the boost converter 20 on the X1 side and the Y1 side. The boost switching element module 21 is arranged in a part of the placement area A1 for the boost converter 20 on the X2 side and the Y2 side with respect to the reactor 22.

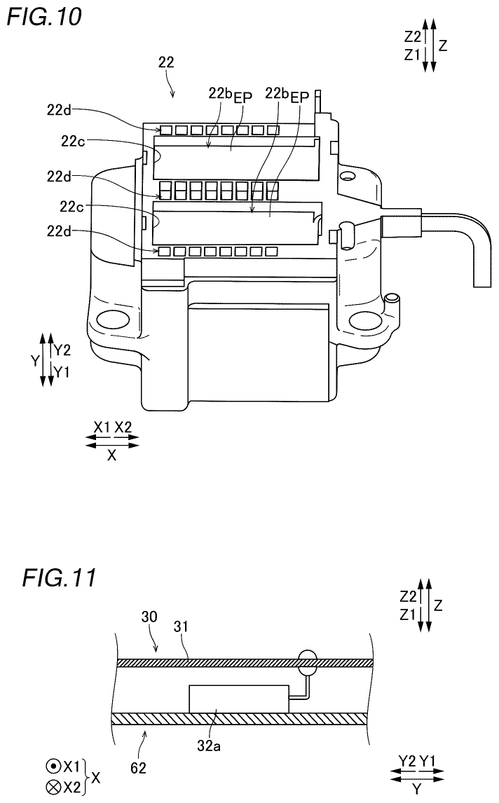

As shown in FIG. 9, the reactor 22 is formed of a resin to include coils 22b parts of which are exposed by resin molding. Specifically, the reactor 22 includes a core 22a, which has a toroidal shape as viewed in the Z direction, and two coils 22b wound on the core 22a. Each of the two coils 22B has a toroidal shape as viewed in the X direction. The reactor 22 is formed to expose Z2-side end parts of the two coils 22b, which have the toroidal shape as viewed in the X direction, by resin molding. As shown in FIG. 10, openings 22c are formed in a Z2-side surface of the reactor 22, which is formed by resin molding, to expose the Z2-side end parts of the two coils 22b.

As shown in FIG. 9, the reactor 22 is arranged to bring the exposed coil parts EP, which are exposed from the resin, of the coils 22b in contact with the contact parts 62e of the boost-converter lid 62 to be in contact with the reactor 22. The contact parts 62e are formed to protrude from the boost-converter lid 62 toward the exposed coil part EP side (Z1 side).

The exposed coil parts EP are the Z2-side end part of the coils 22b, which has the toroidal shape as viewed in the X direction, and correspondingly have a convex shape that protrudes toward the boost-converter lid 62 side (Z2 side). To address this, the contact parts 62e have a concave shape that is arranged at a position corresponding to the convex shape of each exposed coil part EP, and recessed toward the boost-converter lid 62 side. Specifically, the Z1-side ends of the contact parts 62e, which protrude from the boost-converter lid 62 toward the Z1 side have the concave shape recessed toward the Z2 side. Note that the concave shapes are not illustrated in FIGS. 4 and 5.

The contact parts 62e have a protrusion height H that forms a gap G between a part of a surface of the reactor 22 on the exposed coil part EP side (Z2 side) other than the exposed coil parts EP and the boost-converter lid 62 with the contact parts 62e being in contact with the exposed coil parts EP. The reactor 22 is fixed to the boost-converter lid 62 by fasteners (not shown) with the contact parts 62e being in contact with the exposed coil parts EP, and without the part of the surface of the reactor on the exposed coil part EP side other than the exposed coil parts EP being in contact with the boost-converter lid 62.

As shown in FIG. 10, the exposed coil parts EP have a rectangular shape as viewed in a direction (Z direction) in which the reactor 22 and the boost-converter lid 62 are aligned. Specifically, two exposed coil parts EP have an elongated rectangular shape as viewed in the Z direction, are aligned in an extension direction (Y direction) of a shorter side of the elongated rectangular shape.

As shown in FIG. 4, the contact parts 62e have a rectangular shape that overlaps each exposed coil part EP as viewed in the direction (Z direction) in which the reactor and the boost-converter lid 62 are aligned. Specifically, two contact parts 62e have an elongated rectangular shape that overlaps corresponding one of the two exposed coil parts EP as viewed in the Z direction, and are aligned with each other in the extension direction (Y direction) of the shorter side of the elongated rectangular shape.

As shown in FIG. 10, a plurality of holes 22d are formed in parts adjacent to the exposed coil parts EP in the Y direction. The plurality of holes 22d are provided to reduce a weight of the reactor 22, which is formed by resin molding, and to reduce thicker parts (of the resin) when the reactor 22 is formed by resin molding. Reduction of thicker parts in resin molding of the reactor 22 can prevent appearance of sinks (depressions appear due to shrinkage in molding).

### <Configuration of Direct Current/Direct Current Converter>

As shown in FIG. 2, the direct current/direct current converter 30 includes a direct current/direct current converter board 31, and a direct current/direct current converter element 32 mounted on the direct current/direct current converter board 31. The direct current/direct current converter board 31 has a flat plate shape. The direct current/direct current converter elements 32 includes a converter switching element 32a, a transformer 32b, a resonant reactor 32c, and a smoothing reactor 32d. The converter switching element 32a is installed on a part on the back side (Z2 side) with respect to the direct current/direct current converter board 31.

As shown in FIG. 11, the converter switching element 32a is connected to a wiring line of the direct current/direct current converter board 31 by solder. The converter switching element 32a is bonded onto the Z1-side surface of the direct-current/direct-current-converter lid 63 by an insulating adhesive. That is, the direct current/direct current converter 30 includes the converter switching element 32a bonded onto the direct-current/direct-current-converter lid 63.

### Advantages of the Embodiment

In this embodiment, the following advantages are obtained.

In this embodiment, as described above, the boost converter 20 includes a reactor 22 formed of a resin to include a coil 22b a part of which is exposed by resin molding. In addition, the reactor 22 is arranged to bring the exposed coil parts EP, which are exposed from the resin, of coils 22b in contact with the contact parts 62e of the boost-converter lid 62 (lid 60) to be in contact with the reactor 22. According to this configuration, because the exposed coil part EP is in contact with the boost-converter lid 62 through the contact part 62e, heat generated from the reactor 22 can be dissipated to the cooling flow path 51 covered by the boost-converter lid 62 without providing a box-like-shaped lid or the like for dedicated the reactor 22. In this case, because such a box-like-shaped lid or the like for dedicated the reactor 22 is not necessarily provided, it is not necessary to provide a sealing structure for sealing between the box-like-shaped lid dedicated for the reactor 22 and the boost-converter lid 62 arranged to cover the cooling flow path 51. Consequently, it is possible to simplify a structure for cooling the reactor 22. In addition, because the box-like-shaped lid dedicated for the reactor 22 is not provided, it is possible to correspondingly reduce a weight of the power conversion apparatus 100, and to reduce the number of parts of the power conversion apparatus 100.

In this embodiment, as described above, the exposed coil parts EP have a rectangular shape as viewed in a direction in which the reactor 22 and the boost-converter lid (lid 60) 62 are aligned. In addition, the contact part 62e has a rectangular shape that overlaps the exposed coil part EP as viewed in the direction in which the reactor 22 and the boost-converter lid 62 are aligned. Accordingly, because the contact area 62e having the rectangular shape overlaps the exposed coil part EP having the rectangular shape, it is possible to easily increase a contact area between the exposed coil part EP and the contact part 62e.

The contact parts 62e are formed to protrude from the boost-converter lid 62 (lid 60) toward the exposed coil part EP side. Accordingly, because the contact part 62e protrudes from the boost-converter lid 62 toward the exposed coil part EP side so that a distance between the exposed coil part EP and the contact part 62e becomes closer than a distance between the exposed coil part EP and other part of the boost-converter lid 62 other than contact part, it is possible to easily bring the exposed coil part EP in contact with the contact part 62e.

In this embodiment, as described above, the contact parts 62e have a protrusion height H that forms a gap G between a part of a surface of the reactor 22 on the exposed coil part EP side other than the exposed coil parts EP and the boost-converter lid 62 (lid 60) with the contact parts 62e being in contact with the exposed coil parts EP. Accordingly, because a gap G is formed between the part of the surface of the reactor 22 on the exposed coil part EP side other than the exposed coil part EP and the boost-converter lid 62 with the contact part 62e being in contact with the exposed coil part EP, it is possible to prevent that contact between the part of the surface of the reactor 22 on the exposed coil part EP side other than the exposed coil part EP and the boost-converter lid 62 obstructs contact of the contact part 62e with the exposed coil part EP.

In this embodiment, as described above, the exposed coil parts EP have a convex shape that protrudes toward the boost-converter lid 62 (lid 60) side. Also, the contact parts 62e have a concave shape that is arranged at a position corresponding to the convex shape of each exposed coil part EP, and recessed toward the boost-converter lid 62 side. Accordingly, because the exposed coil part EP, which has a convex shape that protrudes toward the boost-converter lid 62 side, can be brought in contact with the contact part 62e, which is arranged at the position corresponding to the convex shape of the exposed coil part EP, and has a concave shape that is recessed toward the boost-converter lid 62 side, it is possible to easily increase a contact area between the exposed coil part EP and the contact part 62e.

In this embodiment, as described above, two exposed coil parts EP have an elongated rectangular shape as viewed in a direction in which the reactor 22 and the boost-converter lid (lid 60) 62 are aligned, and are aligned in an extension direction of a shorter side of the elongated rectangular shape. In addition, two contact parts 62e each of which has an elongated rectangular shape that overlaps corresponding one of the two exposed coil parts EP as viewed in the direction in which the reactor 22 and the boost-converter lid 62 are aligned are aligned with each other in the extension direction of the shorter side of the elongated rectangular shape. Accordingly, because each of the two contact areas 62e having the elongated rectangular shape overlaps corresponding one of the two exposed coil parts EP having the elongated rectangular shape, it is possible to more easily increase a contact area between the exposed coil part EP and the contact part 62e.

In this embodiment, as described above, cooling fins 62c protruding into the cooling flow path 51 are formed at positions of a surface of the boost-converter lid 62 (lid 60) on the cooling flow path 51 side corresponding to contact parts 62e. Accordingly, it is possible to efficiently cool the boost-converter lid 62 by a cooling liquid flowing in the cooling flow path 51 through the cooling fins 62c. Consequently, it is possible to efficiently dissipate heat generated from the reactor 22 to the cooling flow path 51 covered by the boost-converter lid 62.

### Modified Embodiments

Note that the embodiment disclosed this time must be considered as illustrative in all points and not restrictive. The scope of the present invention is not shown by the above description of the embodiments but by the scope of claims for patent, and all modifications (modified embodiments) within the meaning and scope equivalent to the scope of claims for patent are further included.

While the example in which the cooling fins 62c protruding into the cooling flow path 51 are formed at positions of a surface of the boost-converter lid 62 (lid 60) on the cooling flow path 51 side corresponding to contact parts 62e has been shown in the aforementioned embodiment, the embodiment according to the present application is not limited to this. In the present invention, alternatively, no cooling fins protruding into the cooling flow path can be formed at positions of a surface of the lid on a cooling flow path side corresponding to the contact part.

While the example in which two exposed coil parts EP have an elongated rectangular shape as viewed in a direction in which the reactor 22 and the boost-converter lid (lid 60) 62 are aligned, and are aligned in an extension direction of a shorter side of the elongated rectangular shape, and two contact parts 62e each of which has an elongated rectangular shape that overlaps corresponding one of the two exposed coil parts EP as viewed in the direction in which the reactor 22 and the boost-converter lid 62 are aligned are aligned with each other in the extension direction of the shorter side of the elongated rectangular shape has been shown in the aforementioned embodiment, the embodiment of the present application is not limited to this. In the present invention, alternatively, two exposed coil parts each of which has a rectangular shape other than the elongated rectangular shape as viewed in the direction in which the reactor and the lid are aligned can be arranged side by side, and two contact parts each of which has a rectangular shape other than the elongated rectangular shape that overlaps corresponding one of the two exposed coil parts as viewed in the direction in which the reactor and the lid are aligned can be aligned side by side. Also, in the present invention, one exposed coil part can be arranged, and only one contact part can be arranged to overlap the exposed coil part as viewed in the direction in which the reactor and the lid are aligned.

While the example in which the exposed coil parts EP have a convex shape that protrudes toward the boost-converter lid 62 (lid 60) side, and the contact parts 62e have a concave shape that is arranged at a position corresponding to the convex shape of each exposed coil part EP, and recessed toward the boost-converter lid 62 side has been shown in the aforementioned embodiment, the present invention is not limited to this. In the present invention, alternatively, the exposed coil part can have a shape other than the convex shape protruding toward a lid side, and the contact part can be arranged at a position corresponding to the shape of the exposed coil part, and can have a shape other than the concave shape recessed toward the lid side.

While the example in which the contact parts 62e have a protrusion height H that forms a gap G between a part of a surface of the reactor 22 on the exposed coil part EP side other than the exposed coil parts EP and the boost-converter lid 62 (lid 60) with the contact parts 62e being in contact with the exposed coil parts EP has been shown in the aforementioned embodiment, the present invention is not limited to this. In the present invention, alternatively, the contact part can have a protrusion height that forms no gap between a part of a surface of the reactor on an exposed coil part side other than the exposed coil part and the lid with the contact part being in contact with the exposed coil part.

While the example in which the contact parts 62e are formed to protrude from the boost-converter lid 62 (lid 60) toward the exposed coil part EP side has been shown in the aforementioned embodiment, the present invention is not limited to this. In the present invention, alternatively, the contact part can be formed not to protrude from the lid toward the exposed coil part side.

While the example in which the exposed coil part EP has a rectangular shape as viewed in a direction in which the reactor 22 and the boost-converter lid (lid 60) 62 are aligned, and the contact part 62e has a rectangular shape that overlaps the exposed coil part EP as viewed in the direction in which the reactor 22 and the boost-converter lid 62 are aligned has been shown in the aforementioned embodiment, the present invention is not limited to this. In the present invention, alternatively, the exposed coil part can have a shape other than the rectangular shape as viewed in a direction in which the reactor and the lid are aligned, and the contact part can have a shape that overlaps the exposed coil part as viewed in the direction in which the reactor and the lid are aligned other than the rectangular shape.

What is claimed is:

1. A power conversion apparatus, comprising:
a boost converter for boosting direct current power input from a direct current power supply;
an inverter for converting the direct current power boosted by the boost converter into alternate current power, and supplying the alternate current power to a load;
a direct current/direct current converter for transforming the direct current power input from the direct current power supply; and
a base on which the boost converter, the inverter, and the direct current/direct current converter are arranged, wherein
the base includes
a cooler main part including a cooling flow path formed in the cooler main part, and formed of a metal, and
a lid arranged to cover the cooling flow path of the cooler main part, and formed of a metal,
the boost converter includes a reactor formed of a resin to include a coil a part of which is exposed by resin molding, and
the reactor is arranged to bring the exposed coil part, which is exposed from the resin, of the coil in contact with a contact part of the lid to be in contact with the reactor.

2. The power conversion apparatus according to claim 1, wherein
the exposed coil part has a rectangular shape as viewed in a direction in which the reactor and the lid are aligned; and
the contact part has a rectangular shape that overlaps the exposed coil part as viewed in the direction in which the reactor and the lid are aligned.

3. The power conversion apparatus according to claim 1, wherein the contact part is formed to protrude from the lid toward an exposed coil part side.

4. The power conversion apparatus according to claim 3, wherein the contact part has a protrusion height that forms a gap between a part of a surface of the reactor on the exposed coil part side other than the exposed coil part and the lid, with the contact part being in contact with the exposed coil part.

5. The power conversion apparatus according to claim 1, wherein
the exposed coil part has a convex shape that protrudes toward a lid side; and
the contact part is arranged at a position corresponding to the convex shape of the exposed coil part, and has a concave shape that is recessed toward the lid side.

6. The power conversion apparatus according to claim 2, wherein
two exposed coil parts each of which has an elongated rectangular shape as viewed in the direction in which the reactor and the lid are aligned are aligned with each other in an extension direction of a shorter side of the elongated rectangular shape as the exposed coil part; and
two contact parts each of which has an elongated rectangular shape that overlaps corresponding one of the two exposed coil parts as viewed in the direction in which the reactor and the lid are aligned are aligned with each other in the extension direction of the shorter side of the elongated rectangular shape as the contact part.

7. The power conversion apparatus according to claim 1, wherein a cooling fin protruding into the cooling flow path is formed at a position of a surface of the lid on a cooling flow path side corresponding to the contact part.
